(19) United States
(12) Patent Application Publication
(10) Pub. No.: US 2010/0308382 A1
(43) Pub. Date: Dec. 9, 2010

(54) SEMICONDUCTOR STRUCTURES AND METHODS FOR REDUCING SILICON OXIDE UNDERCUTS IN A SEMICONDUCTOR SUBSTRATE

(75) Inventors: Frank S. JOHNSON, Wappinger Falls, NY (US); Andreas KNORR, Wappinger Falls, NY (US)

Correspondence Address: Ingrassia Fisher & Lorenz, P.C. (GF), 7010 E. Cochise Rd., Scottsdale, AZ, 85253, US

(73) Assignee: GLOBALFOUNDRIES INC., Grand Cayman (KY)

(21) Appl. No.: 12/480,279

(22) Filed: Jun. 8, 2009

(51) Int. Cl. H01L 29/78; H01L 21/302; H01L 21/28

(52) U.S. Cl. 257/288; 438/694; 438/299; 257/E29.255; 257/E21.158; 257/E21.214

(57) ABSTRACT

Methods are provided for fabricating semiconductor structures with an etch resistant layer that reduces undercuts in a silicon oxide layer of a semiconductor substrate. The semiconductor substrate is provided having the silicon oxide layer. The etch resistant layer is formed which uses at least a portion of the silicon oxide layer. A silicon-comprising material layer is formed overlying the etch resistant layer. The silicon-comprising material layer has an etch rate greater than an etch rate of the etch resistant layer when subjected to an etchant. The silicon-comprising material layer is etched with an etchant to form a fin structure on the silicon oxide layer. The etch resistant layer may be formed by ion implantation, diffusing nitrogen-supplying species into the silicon oxide layer, or forming an insulator material layer overlying the silicon oxide layer.

### FIELD OF THE INVENTION

The present invention generally relates to semiconductor structures and methods for fabricating semiconductor structures, and more particularly relates to stabilized silicon structures and methods for reducing undercuts during formation of semiconductor structures, including FinFET gate structures.

### BACKGROUND OF THE INVENTION

In contrast to traditional planar metal-oxide-semiconductor field-effect transistors (MOSFETs), which are fabricated using conventional lithographic fabrication methods, nonplanar FETs incorporate various vertical transistor structures, and typically include two or more gate structures formed in parallel. One such semiconductor structure is the “FinFET,” which takes its name from the multiple thin silicon “fin structures” that are used to form the respective gate channels, and which are typically on the order of tens of nanometers in width.

More particularly, referring to the exemplary prior art nonplanar FET structure shown in FIG. 1, a FinFET 10 generally includes two or more parallel silicon fin structures (or simply “fins”) 12. The fin structures are typically formed on a semiconductor substrate 14 (FIG. 2) with the fin structures extending between a common drain electrode and a common source electrode (not shown). A conductive gate structure 16 “wraps around” three sides of both fins 12, and is separated from the fins by a standard gate oxide layer 18. Fins 12 may be suitably doped to produce the desired FET polarity, as is known in the art, such that a gate channel is formed within the near surface of the fins adjacent to gate oxide 18.

FIG. 2 illustrates, in cross-section, a conventional semiconductor substrate 14 comprising a support substrate 20, a silicon oxide layer 22, and a silicon-comprising material layer 24 overlying the silicon oxide layer. The silicon-comprising material from which the fin structures are formed and the silicon oxide layer form a silicon on insulator (SOI) structure 26 that, in turn, is supported by the support substrate 20. Fin structures may be formed using any conventional process, including but not limited to, conventional photolithographic and anisotropic etching processes (e.g. reactive ion etching (RIE) or the like). FIGS. 3 and 4 illustrate fin structures 12 formed on the silicon oxide layer 22 from etching the silicon-comprising material layer (not shown in FIGS. 3 and 4). After formation and cleaning of the fin structures, FinFET processing steps include forming the gate structures 16.

Unfortunately, as shown in FIG. 3, etching of the silicon-comprising material layer (not shown in FIG. 3) to form fin structures 12 causes some overetching in the underlying silicon oxide layer 22. Most silicon etchants also etch silicon oxide so any etching of the silicon-comprising material layer will also etch the underlying silicon oxide layer 22. Oxide will etch faster than silicon to make the silicon oxide layer 22 thinner in the vertical direction and laterally (under the silicon-comprising fin structures). Such overetching forms silicon oxide pedestals 25 which marginally support the fin structures.

Further overetching of the silicon oxide layer 22 during repeated cleans (particularly Hydrofluoric acid (HF) cleans) and etches and other processes involved with formation of the components of FinFET structures after fin formation results in undercut regions 28 (or “undercuts”) under the fin structures (See FIG. 4). These undercut regions 28 cause a loss of mechanical support for the fin structures on the silicon oxide layer. If the fin structures are not adequately supported (for example by another structure such as a gate), the inadequately supported fin structures may break off from the silicon oxide layer (herein referred to as a “floating fin structure” 30) causing a missing gate and resulting in a defective die.

Accordingly, it is desirable to provide methods for fabricating a semiconductor structure with a semiconductor substrate having an etch resistant layer that resists overetching of the silicon oxide layer during fabrication of the semiconductor structure. In addition, it is desirable to provide methods for simultaneously making etches and other processes more selective to the silicon oxide layer and to provide mechanical stability for the structures etched in the silicon-comprising material layer. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Methods for fabricating semiconductor structures having an etch resistant layer to reduce undercuts in the silicon oxide layer are provided herein. In accordance with one exemplary embodiment, a method for fabricating the semiconductor structure comprises providing a semiconductor substrate having a silicon oxide layer and forming the etch resistant layer using at least a portion of the silicon oxide layer. A silicon-comprising material layer is formed overlying the etch resistant layer. A fin structure is formed by etching the silicon-comprising material layer using an etchant. The silicon-comprising material layer has an etch rate greater than the etch rate of the etch resistance layer when subjected to the etchant. The etch resistant layer may be formed by depositing an etch resistant insulator material layer overlying the silicon oxide layer, implanting ions into the silicon oxide layer, or diffusing nitrogen-supplying species into the silicon oxide layer.

### BRIEF DESCRIPTION OF THE DRAWINGS

The present invention will hereinafter be described in conjunction with the following drawing figures, wherein like numerals denote like elements, and

FIG. 1 is an isometric schematic view of a FinFET structure available in the prior art;

FIG. 2 illustrates, in cross section, a portion of a conventional semiconductor substrate available in the prior art including a silicon substrate, a silicon oxide layer overlying the silicon substrate, and a silicon-comprising material layer overlying the silicon oxide layer;

FIG. 3 illustrates, in cross section, fin structures on the silicon oxide layer with the fin structures supported on silicon oxide pedestals formed by overetching into the silicon oxide layer;

FIG. 4 illustrates, in cross section, undercut regions beneath the fin structures of FIG. 3 as a result of significant overetching into the silicon oxide layer during gate formation;

FIG. 5 illustrates, in cross section, methods for implanting ions into the silicon oxide layer of the semiconductor substrate to form an ion implanted silicon oxide etch resistant layer, in accordance with exemplary embodiments of the present invention;

FIG. 6 illustrates, a cross section, methods for diffusing nitrogen-comprising material into the silicon oxide layer of the semiconductor substrate to form an etch resistant layer of silicon oxynitride, in accordance with exemplary embodiments of the present invention;

FIG. 7 illustrates, in cross section, methods for forming an insulator material layer comprised of etch resistant insulator material overlying the silicon oxide layer of the semiconductor substrate, in accordance with exemplary embodiments of the invention; and

FIG. 8 illustrates, in cross section, fin structures formed on the etch resistant layer of the semiconductor substrate of FIG. 7.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

FIGS. 5-8 illustrate, in cross section, methods for reducing fin structure undercuts during FinFET fabrication on a semiconductor substrate. While the various embodiments particularly refer to the fabrication of FinFET semiconductor structures including the formation of fin structures, it will be understood that the invention is not so limited. For example, undercut structures other than fin structures may be formed by etching a silicon-comprising material layer of a semiconductor substrate which may result in overetching of the underlying silicon oxide layer forming undercut regions therein. In addition, it will be understood that the methods described can be used for forming semiconductor structures other than FinFET structures.

In accordance with an exemplary embodiment of the present invention, a method for fabricating a semiconductor structure (e.g. a FinFET structure 10) includes the step of providing a semiconductor substrate 14 such as shown in FIG. 2. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The semiconductor material is preferably a silicon substrate. The semiconductor substrate 14 comprises a silicon oxide (BOX) layer 22 disposed on a support substrate 20. Support substrate 20 is preferably a silicon substrate, which can be either N-type or P-type silicon. A silicon-comprising material layer 24 overlies the silicon oxide layer.

Referring to FIG. 5, in accordance with an exemplary embodiment of the present invention, a method of fabricating the semiconductor structure also includes the step of forming an etch resistant layer 32 using at least a portion of the silicon oxide layer of the semiconductor substrate. The etch resistant layer 32 may be formed by implanting ions 36 into the silicon oxide layer of the semiconductor substrate to form the etch resistant layer of ion implanted silicon oxide. The ion implanted silicon oxide etch resistant layer may be formed using conventional ion implantation methods. As indicated by arrow 34, boron ions may be implanted into the silicon oxide layer to form the ion implanted silicon oxide etch resistant layer 32. The semiconductor substrate having ions implanted into the silicon oxide layer to form the etch resistant layer 32 is herein referred to by reference numeral 38. Other impurities that are known to retard the etching of silicon oxide, such as nitrogen ions and others ions including molecular and elemental ions can be used instead of or in conjunction with boron implantation. While ions are shown in FIG. 5 as being implanted in an upper portion of the silicon oxide layer, it will be understood that the invention is not so limited. A relatively low energy implantation can be introduced directly to the surface of the silicon oxide layer prior to completion of SOI structure fabrication, or be introduced by implanting through the silicon oxide surface of the completed substrate, using a higher energy. The etch resistant layer may be formed using a portion of or the entire silicon oxide layer.

As used herein, an “etch resistant layer” will encompass an insulating layer that exhibits a lower etch rate and thus is more resistive to overetching than the silicon oxide layer when subjected to the same etch chemistries, and specifically to an etch chemistry designed to etch a silicon-comprising material. As used hereinafter, the term “overetching” will encompass erosion of the silicon oxide layer of a semiconductor substrate as a result of processes such as cleans and etches and the like involved with the formation of semiconductor structures, including FinFET structures. As used herein, the term “fin structure” and “fin structures” will encompass fin-like vertical orthogonal structures having a high aspect ratio, including those of a FinFET structure.

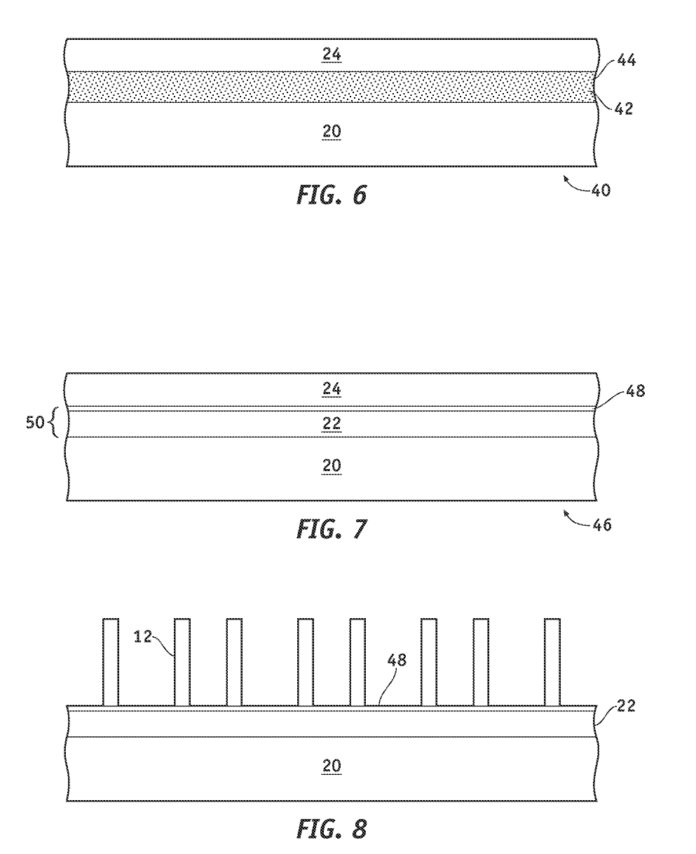

FIG. 6 illustrates, in cross section, a semiconductor substrate 40 fabricated by the method in accordance with yet another embodiment of the invention comprising diffusing nitrogen-comprising material 42 into the silicon oxide layer to form the etch resistant layer 44 of silicon oxynitride. The semiconductor substrate having nitrogen-comprising material diffused into the silicon oxide layer to form etch resistant layer 44 is herein referred to by reference numeral 40. The nitrogen-comprising material may be selected from nitrogen-supplying species. The nitrogen-supplying species may be selected from ammonia, nitrogen gas, or another nitrogen-containing molecule. The etch resistant layer may be formed using conventional nitridation methods, such as thermal nitridation or plasma nitridation. The thermal nitridation method typically takes place at temperatures of between about 400 degrees to about 1100 degrees Celsius. The plasma nitridation method may use the same nitrogen-comprising materials as stated above using conventional plasma nitriding conditions at lower temperatures.

While the nitrogen-comprising material is shown diffused in FIG. 6 throughout the silicon oxide layer, it will be understood that the invention is not so limited. The etch resistant layer may be formed using a portion of or the entire silicon oxide layer.

FIG. 7 illustrates a semiconductor substrate 46 fabricated by the method in accordance with yet another embodiment of the invention comprising depositing an insulator material layer 48 overlying the silicon oxide layer 22 of the semiconductor substrate. The semiconductor substrate having the insulator material layer overlying the silicon oxide layer to form the etch resistant layer 50 is herein referred to by reference numeral 46. An etch resistant insulator material may be used to form the insulator material layer. The etch resistant insulator material may be selected from the group consisting of silicon nitride, silicon carbide, or a combination thereof. The thickness of the insulator material layer ranges from about 2.5 nm to about 250 nm. While the insulator material layer 48 overlying the silicon oxide layer 22 is shown in FIG. 7 to be relatively thin as compared to the silicon oxide layer, it is to be appreciated that the insulator material layer may have a smaller thickness than the silicon oxide layer, the same thickness as the silicon oxide layer, or a larger thickness than the silicon oxide layer. As a result of the added etch resistant layer, the original silicon oxide layer can be thinned or eliminated, if desired. The amount of insulator material deposited depends on a balance of manufacturing costs, the capacitance associated with the dielectric constant of the etch resistant insulator material in combination with the silicon oxide layer, and the etch resistance needed at a particular depth of the insulator material.

FIG. 8 illustrates fin structures 12 formed on the insulator material layer 48 of semiconductor substrate 46. An etchant may be used to etch the silicon-comprising material layer (not shown in FIG. 8) to form the fin structures 12. The silicon-comprising material layer (not shown in FIG. 8) has an etch rate greater than the etch rate of the etch resistant layer when subjected to an etchant. The etchant, as known to one skilled in the art, may comprise hydrofluoric acid, bromine or other known etch chemistries.

The fin structures 12 may be formed on the etch resistant layer of semiconductor substrates 38 and 40 in the same manner as described above with respect to semiconductor substrate 46.

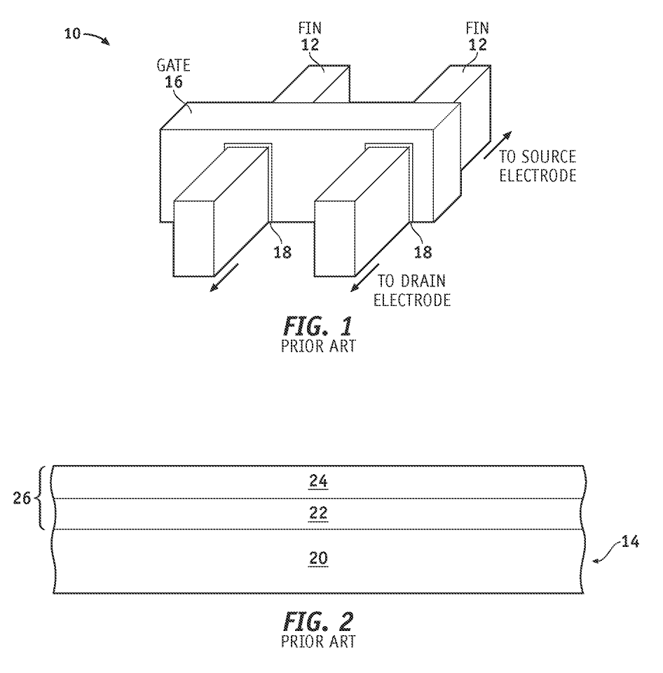

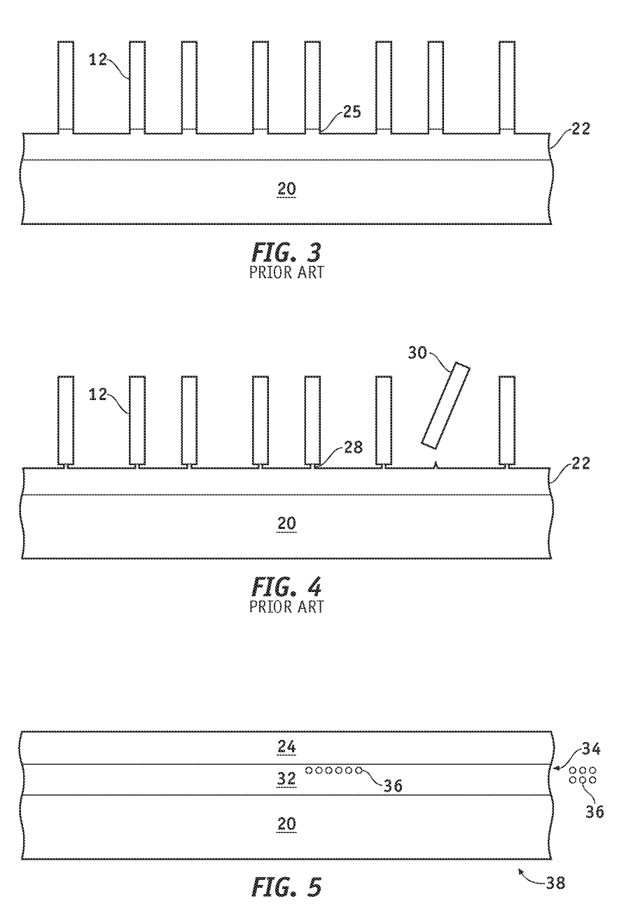

After the fin structures 12 are formed and cleaned, conventional fabrication processing can be performed to complete the FinFET as illustrated in FIG. 1. A gate insulator is formed overlying the fin structures and a gate electrode forming material such as polycrystalline silicon is deposited over the gate insulator. The gate electrode forming material is patterned to form at least one gate electrode 16 as is known in the art. The gate electrode is then used as an ion implantation mask and conductivity determining ions are implanted into exposed portions of the fin structures in self alignment with the gate electrode to form source and drain regions. As those of skill in the art will appreciate, the ion implantation mask may also include sidewall spacers formed on the sides of the gate electrodes and multiple ion implantations may be used to form the source and drain regions.

Accordingly, methods for fabricating semiconductor structures from a semiconductor substrate having an etch resistant layer to resist overetching of the silicon oxide layer have been provided. FinFET processes such as cleans and etches or the like may be performed with increased selectively. As a result, there is less overetching of the silicon oxide layer when forming the silicon fin structures resulting in fewer undercuts. With fewer undercuts, the fin structures exhibit increased mechanical stability thereby reducing die defects. In addition, more selective etching processes allow for additional process margin on other processing steps.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating a semiconductor structure comprising the steps of:
providing a semiconductor substrate having a silicon oxide layer;
forming an etch resistant layer using at least a portion of the silicon oxide layer;
forming a silicon-comprising material layer overlying the etch resistant layer, the silicon-comprising material layer having an etch rate greater than an etch rate of the etch resistant layer when subject to an etchant; and
etching the silicon-comprising material layer using the etchant to form a fin structure on the silicon oxide layer.

2. The method of claim 1, wherein the step of forming the etch resistant layer comprises depositing an insulator material layer overlying the silicon oxide layer.

3. The method of claim 2, wherein the step of depositing the insulator material layer comprises depositing an insulator material comprising silicon nitride, silicon carbide, or a combination thereof.

4. The method of claim 3, wherein the step of depositing the insulator material layer comprises depositing the insulator material layer with a thickness of about 2.5 nm to about 250 nm.

5. The method of claim 1, wherein the step of forming the etch resistant layer comprises implanting ions into the silicon oxide layer.

6. The method of claim 5, wherein the step of implanting ions into the silicon oxide layer comprises implanting the silicon oxide layer with at least one of boron ions and nitrogen ions.

7. The method of claim 1, wherein the step of forming the etch resistant layer comprises diffusing nitrogen-comprising material into the silicon oxide layer.

8. The method of claim 7, wherein the step of diffusing nitrogen-comprising material into the silicon oxide layer comprises exposing the silicon oxide layer to nitrogen-supplying species.

9. The method of claim 7, wherein the step of diffusing nitrogen-comprising material into the silicon oxide layer comprises exposing the silicon oxide layer to the nitrogen-supplying species at temperatures of about 400 degrees to about 1100 degrees Celsius.

10. A method of reducing fin structure undercut during FinFET fabrication, comprising the steps of:
providing a semiconductor substrate having a silicon oxide layer;
forming an etch resistant layer using at least a portion of the silicon oxide layer;
forming a silicon-comprising material layer overlying the etch resistant layer, the silicon-comprising material layer having an etch rate greater than an etch rate of the etch resistant layer when subjected to an etchant;
etching the silicon-comprising material layer to form a fin structure on the etch resistant layer;
forming a source region adjacent a first end of the fin structure and a drain region adjacent a second end of the fin structure;
forming a gate over the fin structure, and
wherein the etch resistant layer reduces fin structure undercut during fin structure and gate formation.

11. The method of claim 10, wherein the step of forming the etch resistant layer comprises depositing an insulator material layer overlying the silicon oxide layer.

12. The method of claim 11, wherein the step of depositing the insulator material layer comprises depositing an insulator material comprising silicon nitride, silicon carbide, or a combination thereof.

13. The method of claim 12, wherein the step of depositing the insulator material layer comprises depositing the insulator material to a thickness of about 2.5 nm to about 250 nm.

14. The method of claim 10, wherein the step of forming the etch resistant layer comprises implanting ions into the silicon oxide layer.

15. The method of claim 14, wherein the step of implanting ions into the silicon oxide layer comprises implanting the silicon oxide layer with at least one of boron ions and nitrogen ions.

16. The method of claim 10, wherein the step of forming the etch resistant layer comprises diffusing nitrogen-comprising material into the silicon oxide layer.

17. The method of claim 16, wherein the step of diffusing nitrogen-comprising material into the silicon oxide layer comprises exposing the silicon oxide layer to nitrogen-supplying species.

18. The method of claim 16, wherein the step of diffusing nitrogen-comprising material into the silicon oxide layer comprises exposing the silicon oxide layer to nitrogen-supplying species at temperatures of about 400 degrees to about 1100 degrees Celsius.

19. The method of claim 16, wherein the step of diffusing nitrogen-comprising material into the silicon oxide layer comprises exposing the silicon oxide layer to nitrogen-containing plasma.

20. A semiconductor structure comprising:
a semiconductor substrate having a silicon oxide layer;
an etch resistant layer using at least a portion of the silicon oxide layer;
a silicon-comprising material layer overlying the etch resistant layer; the silicon-comprising material layer having an etch rate greater than an etch rate of the etch resistant layer when subjected to an etchant;
a fin structure formed from the silicon-comprising material layer overlying the etch resistant layer, wherein the etch resistant layer comprises one of a ion implanted silicon oxide layer, a nitrided oxide layer, or an insulator material layer overlying the silicon oxide layer;
source and drain regions adjacent opposing ends of the fin structure; and
a gate structure over the fin structure.
